(19) United States
(12) Patent Application Publication
(10) Pub. No.: US 2010/0219455 A1
(43) Pub. Date: Sep. 2, 2010

(54) III-NITRIDE SEMICONDUCTOR FIELD EFFECT TRANSISTOR

(76) Inventors: Yuki Niiyama, Tokyo (JP); Seikoh Yoshida, Tokyo (JP); Takehiko Nomura, Tokyo (JP); Hiroshi Kambayashi, Tokyo (JP)

Correspondence Address: Kubotera & Associates, LLC, 200 Daingerfield Rd, Suite 202, Alexandria, VA, 22314, US

(21) Appl. No.: 12/699,957

(22) Filed: Feb. 4, 2010

Related U.S. Application Data
(63) Continuation of application No. 12/506,035, filed on Jul. 20, 2009.
Application No. 12/506,035 is a continuation of application No. 12/325,091, filed on Nov. 28, 2008, now abandoned.
Application No. 12/325,091 is a continuation of application No. 12/059,154, filed on Mar. 31, 2008, now abandoned.

(51) Int. Cl. H01L 29/20; H01L 29/78

(52) U.S. Cl. 257/288; 257/615; 257/E29.089; 257/E29.255

(57) ABSTRACT

An active layer of a first conductive-type includes a channel area. A first contact area and a second contact area of a second conductive-type are formed at positions across the channel area. A source electrode is formed on the first contact area. A drain electrode is formed on the second contact area. A gate electrode is formed above the channel area via a gate insulating layer. A reduced surface field zone of the second conductive-type is formed in the channel area at a position close to the second contact area. Thickness of the reduced surface field zone is 30 nanometers to 100 nanometers.

### CROSS REFERENCE

This application is a continuation of application Ser. No. 12/506,035, which was filed Jul. 20, 2009, which is a continuation of application Ser. No. 12/325,091 filed Nov. 28, 2008, which is a continuation of application Ser. No. 12/059,154 filed Mar. 31, 2008, now abandoned, which claims priority to Japanese Application No. 2007-253362 which was filed Sep. 28, 2007.

### BACKGROUND OF THE INVENTION

1. Field of the Invention

The present invention relates to a III-nitride semiconductor normally-off-type field effect transistor, and more particularly, to a field effect transistor having high carrier mobility and high breakdown voltage.

2. Description of the Related Art

The wide band gap semiconductors represented by III-nitride semiconductors attract a considerable attention as a material for high-temperature, high-power, and high-frequency semiconductor devices because of their excellent physical properties including breakdown voltage, saturation carrier velocity, and thermal conductivity higher than those of silicon. For example, an AlGaN/GaN heterojunction field effect transistor (HFET) has high carrier concentration and high electron mobility because of a two-dimensional electron gas generated on a boundary of the heterostructure due to a piezoelectric field. The HFET is suitable for a high-power switching element because of its characteristics including low on-resistance, high-speed switching, and operability in high temperature (see, “Normally-off GaN-MISFET with well-controlled threshold voltage”, M. Kuraguchi, et al., International Workshop on Nitride Semiconductors 2006 (IWN 2006), Oct. 22-27, 2006, Kyoto, Japan, WeED1-4).

A typical AlGaN/GaN HFET is a normally-on-type device in which current flows from drain to source region when no voltage is applied to a gate electrode, and the current stops when a negative voltage is applied to the gate electrode. However, it is preferable from viewpoint of security and safety of electric applications in case of a failure to use as the power switching element a normally-off-type device in which current stops when no voltage is applied to the gate electrode, and current flows when a positive voltage is applied to the gate electrode.

A metal oxide semiconductor field effect transistor (MOSFET) structure is an example of a normally-off-type structure. FIG. 7 is a side view of a conventional MOSFET 200. The MOSFET 200 includes a substrate 201, an active layer 203 formed with p-GaN including a channel area 203a, and contact areas 210 and 211 formed with n+-GaN at positions across the channel area 203a. A source electrode 206 is formed on the contact area 210, and a drain electrode 207 is formed on the contact area 211. A gate electrode 208 is formed on the channel area 203a via a gate insulating layer 205. A reduced surface field zone (RESURF zone) 212 for reducing the electric-field concentration is formed in the channel area 203a from the gate insulating layer 205 to a gate-side end of the contact area 211.

The RESURF zone 212 prevents occurrence of dielectric breakdown, which is likely to occur when a drain voltage increases during an OFF state (zero gate bias), by reducing an electric-field concentration near the gate electrode 208.

In the conventional MOSFET including the RESURF zone, when a sheet carrier concentration of the RESURF zone is too high, the dielectric breakdown is likely to occur on a surface of the gate insulating layer near its drain-side end. On the other hand, when the sheet carrier concentration of the RESURF zone 212 is too low, the dielectric breakdown is likely to occur on a surface of the drain-side contact area near its gate-side end. Therefore, the sheet carrier concentration needs to be precisely controlled.

Moreover, even if the sheet carrier concentration is successfully controlled to a desired level, it is difficult to obtain a low sheet resistance, and therefore a sufficient drain current can hardly be obtained.

### SUMMARY OF THE INVENTION

It is an object of the present invention to at least partially solve the problems in the conventional technology.

According to an aspect of the present invention, there is provided a III-nitride semiconductor field effect transistor including an active layer of a first conductive-type including a channel area; a first contact area and a second contact area of a second conductive-type formed at positions across the channel area; a source electrode formed on the first contact area; a drain electrode formed on the second contact area; a gate electrode formed above the channel area via a gate insulating layer; and a reduced surface field zone of the second conductive-type formed in the channel area at a position close to the second contact area. Thickness of the reduced surface field zone is 30 nanometers to 100 nanometers.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a side view of a MOSFET according to a first embodiment of the present invention;

FIG. 2 is a schematic diagram of the MOSFET shown in FIG. 1 for explaining resistance components of a current path;

FIG. 3 is a graph for explaining a relation between a sheet carrier concentration of a RESURF zone in the MOSFET shown in FIG. 1 and breakdown voltage;

FIG. 4 is a graph for explaining a relation between an ion-implantation depth of the RESURF zone in the MOSFET shown in FIG. 1 and resistance;

FIG. 5 is a side view of a MOSFET according to a first modification the first embodiment;

FIG. 6 is a side view of a MOSFET according to a second modification of the first embodiment; and

FIG. 7 is a side view of a conventional MOSFET.

### DETAILED DESCRIPTION OF THE PREFERRED EMBODIMENTS

Exemplary embodiments of the present invention are described in detail below with reference to the accompanying drawings.

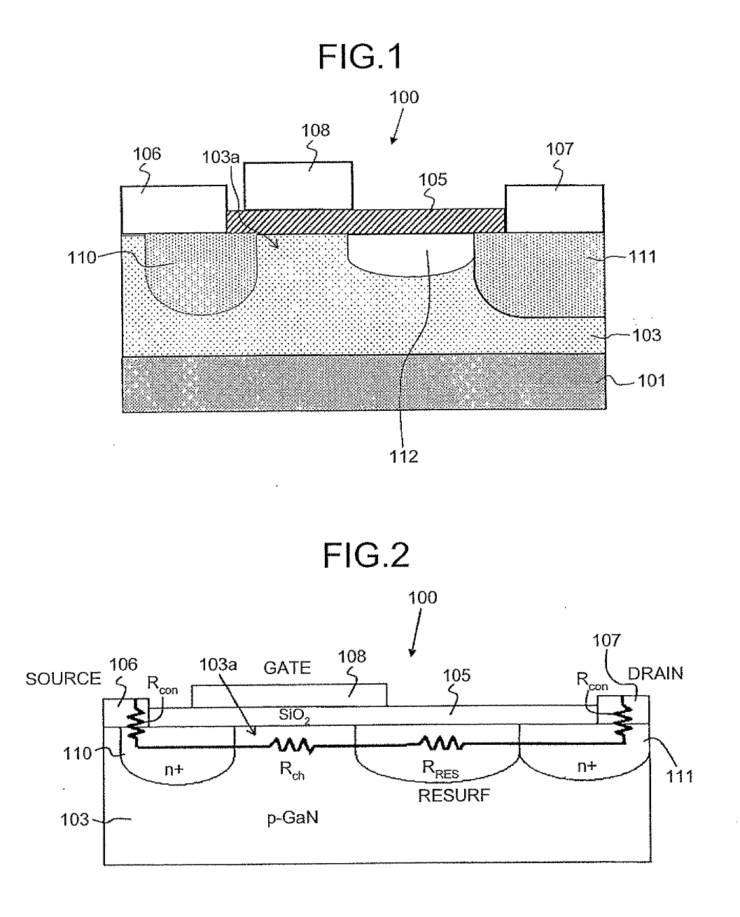

FIG. 1 is a side view of a MOSFET 100 according to a first embodiment of the present invention. The MOSFET 100 is a normally-off-type MOSFET, which is formed mainly with III-nitride semiconductor.

The MOSFET 100 includes a silicon substrate 101, an active layer 103 that is formed with p-GaN on the substrate 101, a source electrode 106, a drain electrode 107, and a gate electrode 108. The active layer 103 includes a channel area 103a, contact areas 110 and 111 at positions across the channel area 103a. The source electrode 106 makes an ohmic contact to the contact area 110, and the drain electrode 107 make an ohmic contact to the contact area 111. The gate electrode 108 is formed on the channel area 103a via a gate insulating layer 105. The active layer 103 includes a RESURF zone 112 between a drain-side end under the gate electrode 108 and the contact area 111.

Materials such as sapphire, Si, SiC, GaN, ZrB₂, and ZnO can be used for the substrate 101. The active layer 103 is formed on the substrate by epitaxial growth with GaN that is doped with a p-type impurity, for example, Mg at a predetermined amount. The active layer 103 can be formed either via a buffer layer (not shown) or directly on the substrate 101.

The contact areas 110 and 111 are n⁺-GaN areas having an electron concentration of about 5×10¹⁹ cm⁻³ that are formed by doping an n-type impurity, for example, Si in the active layer 103 using an ion implantation. The contact areas 110 and 111 can be formed by another technique such as selective regrowth or thermal diffusion of impurity.

The RESURF zone 112 is an n-GaN area that is formed to increase the breakdown voltage. The RESURF zone 112 can reduce electric-field concentration on a surface of the active layer 103 thereby preventing occurrence of the dielectric breakdown.

As shown in FIG. 4, if an ion-implantation depth is 30 nanometers or smaller, resistance increases, while if the ion-implantation depth is 100 nanometers or larger, the resistance also increases. Therefore, the RESURF zone 112 is formed to be 30 nanometers to 100 nanometers thick. This is because if the thickness is larger than 100 nanometers, a carrier concentration per unit volume of the RESURF zone 112 decreases, which results in increasing of a sheet resistance. If the thickness is smaller than 30 nanometers, a cross-section of the current path decreases, which results in decreasing of conductance and increasing of resistance. To obtain the ion-implantation depth of 30 nanometers or smaller, it is necessary to decrease acceleration energy. However, because an ordinary ion-implantation device cannot set the acceleration energy to almost 25 keV or lower, it is difficult to obtain the ion-implantation depth of 30 nanometers or smaller.

Recently a cluster ion implantation and a plasma doping technique have been used for a shallow doping technique, but these systems is usually so expensive that those are not suitable for less than 30 nanometers depth doping technique at present.

It is widely known that if an impurity is doped in a given area by an ion implantation, the impurity concentration shows a substantially normal distribution with respect to the depth direction. If a RESURF zone is formed by an ion implantation, a distance between a surface and a portion where the impurity concentration decreases to a value one digit smaller than the maximum value is measured as a thickness of the RESURF zone.

FIG. 2 is a schematic diagram of the MOSFET 100 for explaining resistance components of the current path. In a non-reduced surface field zone type metal oxide semiconductor field effect transistor (NR-type MOSFET) that includes no RESURF zone, an on-resistance RNR is a series resistance of a first resistance component Rcon, a channel resistance Rch, and a second resistance component Rcon. The first resistance component Rcon is a resistance between a source electrode and a first contact area (n⁺-type GaN layer) contacting with the source electrode. The second resistance component Rcon is a resistance between a drain electrode and a second contact area (n⁺-type GaN layer) contacting with the drain electrode. An on-resistance of the MOSFET 100 is a sum of the on-resistance RNR and a resistance component RRES at the RESURF zone 112.

A drain current Id in the NR-type MOSFET is calculated by

$$\begin{matrix}\begin{matrix}{I}_{d} = \frac{1}{2} \frac{{W}_{ch}}{{L}_{ch}} {μ}_{NR} {C}_{ox} \{ 2 ( {V}_{g} - {V}_{th} ) {V}_{ds} - {V}_{ds}^{2} \} & ( Linear region )\end{matrix} & ( 1 ) \\ \begin{matrix}{I}_{d} = \frac{1}{2} \frac{{W}_{ch}}{{L}_{ch}} {μ}_{NR} {{C}_{ox} ( {V}_{g} - {V}_{th} )}^{2} & ( Saturated region )\end{matrix} & ( 2 ) \\ {C}_{ox} = \frac{{ɛ}_{0} {ɛ}_{oc}}{{d}_{ox}} & ( 3 )\end{matrix}$$

where W_{ch} is channel width, L_{ch} is channel length, μ_{NR} is mobility of the NR-type MOSFET, i.e., mobility in the presence of the resistances at the first contact area, the second contact area, and the channel, Cₒₓ is capacitance of oxidized film per unit area, V_{g} is gate voltage, Vₜₕ is threshold voltage, and V_{ds} is drain voltage, ε₀ is vacuum permittivity, and εₒₓ is relative permittivity of the oxidized film, and dₒₓ is thickness of the gate oxidized film.

A drain current I_{d,RES} of the MOSFET 100 is calculated by

$${I}_{d , RES} = \frac{{V}_{ds}}{{R}_{NR} + {R}_{RES}} = \frac{{V}_{ds}}{\frac{{V}_{ds}}{{I}_{d}} + \frac{{L}_{RES}}{{W}_{ch}} {R}_{RES , sheet}} \qquad ( 4 )$$

where L_{RES} is RESURF zone length (length of the RESURF zone 112), and R_{RES,sheet} is sheet resistance of the RESURF zone 112.

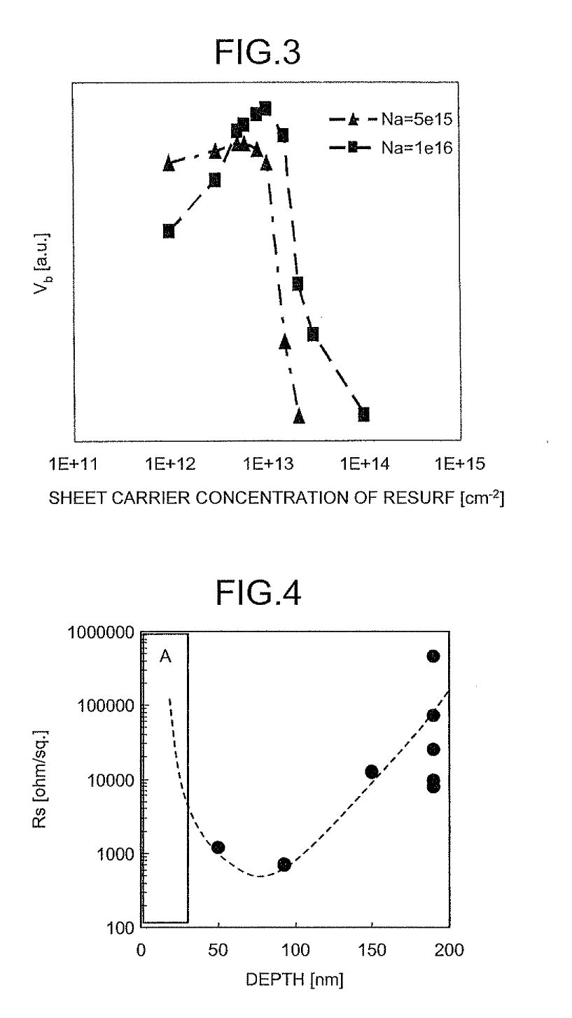

FIG. 3 is a graph for explaining a relation between the sheet carrier concentration of the RESURF zone 112 and the breakdown voltage. It is found from the graph that the MOSFET 100 can obtain high breakdown voltage when the sheet carrier concentration is 1×10¹² cm⁻² to 5×10¹³ cm⁻².

Given below is an explanation about a process of fabricating the MOSFET 100.

Firstly, a p-GaN layer is epitaxially grown on the substrate 101 using a metal-organic chemical vapor deposition (MOCVD). Mg in a concentration of 1×10¹⁵ cm⁻³ to 5×10¹⁷ cm⁻³ is doped as a p-type dopant.

Secondly, the p-type layer is patterned for isolation by applying a photoresist on the surface and then exposed with a light. Isolation is performed by etching the p-type layer, for example, using dry etching such as an inductively coupled plasma (ICP) etching or a reactive ion etching (RIE) and then removing the photoresist with an organic solvent such as an acetone solvent.

Thirdly, a first mask layer is formed with SiO₂ or the like. An opening for forming a contact layer is formed on the first mask layer by a photolithographic technique. Two n+ areas as the contact areas 110 and 111 are formed by doping an n-type dopant, for example, Si through the opening of the first mask layer by an ion implantation. After that, the first mask layer is removed with a fluorinated acid-based solvent.

Fourthly, the n-type RESURF zone 112 is formed by forming a second mask layer with SiO₂ or the like and performing a process in the same manner as the contact areas 110 and 111 are formed. In an ion implantation for forming the RESURF zone 112, an n-type dopant is doped in the second mask layer at such an accelerating voltage that a thickness of the RESURF zone 112 can be 30 nanometers to 100 nanometers.

Fifthly, a third mask layer is formed with SiO₂ or the like. After the third mask layer is formed, the substrate is annealed in an N atmosphere at 1200° C. for 10 seconds to activate the dopant in the element. The third mask layer is then removed with a fluorinated acid-based solvent.

Sixthly, the gate insulating layer 105 is formed with SiO₂ or the like on a part of the channel area 103a between the contact areas 110 and 111 by, for example, a photolithographic technique. The source electrode 106 and the drain electrode 107 that make an ohmic contact to n⁺-GaN such as Ti/Al are formed on the contact area 110 and the contact area 111, respectively.

Seventhly, the gate electrode 108 is formed on the gate insulating layer 105 with either a metal such as polysilicon, Au, Pt, or Ni or an alloy including two or more metals selected from among the above-described metals.

Thus, the MOSFET 100 is finally fabricated.

The III-nitride semiconductor field effect transistor according to an embodiment of the present invention can be fabricated in various manners within the scope of the present invention in addition to the manner according to the first embodiment.

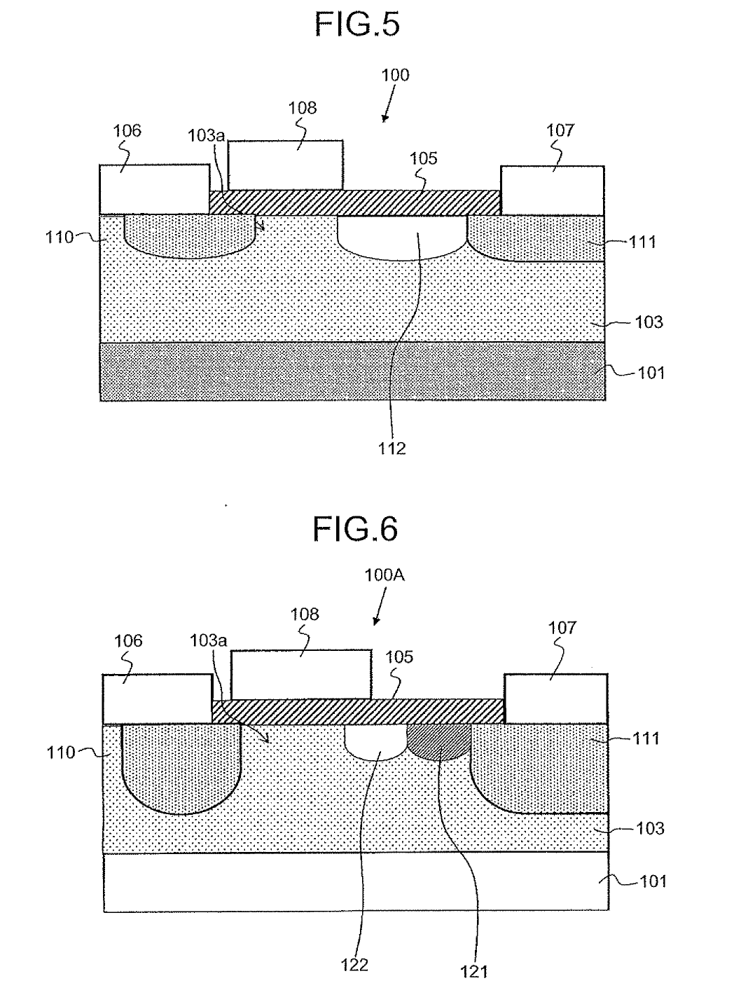

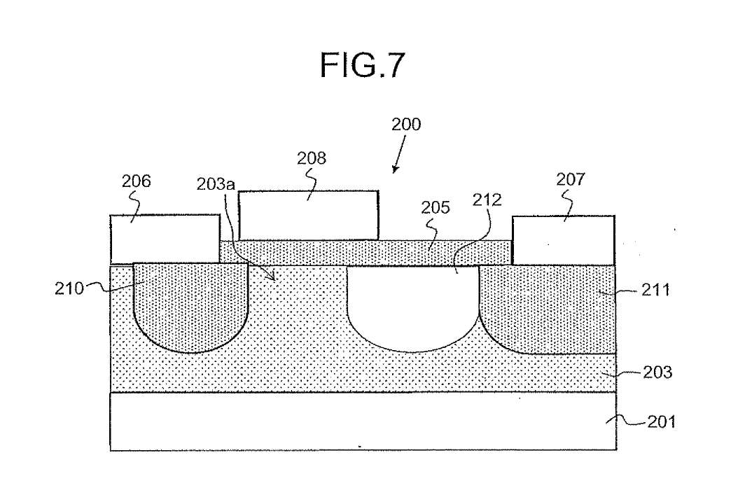

For example, a depletion layer is generated by reacting doner ions (positively charged) in the contact area 110 with acceptor ions (negatively charged) in the channel area 103a. If the contact area 110 is relatively thick, the contact area 110 includes more doner ions and therefore an amount of required acceptor ions in the channel area 103a increases. As a result, the number of positive holes as carriers in the channel area 103a decreases, which results in decreasing of the threshold voltage. On the other hand, if the contact areas 110 and 111 are thin, the conductance decreases, and the resistance increases. As a result, the on-resistance increases. Accordingly, as shown in FIG. 5, a thickness of the contact area 110 and/or the contact area 111 is preferably in a rage from 30 nanometers to 100 nanometers as well as the thickness of the RESURF zone 112.

The RESURF zone according to the first embodiment is a single area having a substantially uniform sheet carrier concentration. In contrast, a MOSFET 100A according to another embodiment of the present invention includes a plurality of RESURF zones 121 and 122 having different sheet carrier concentrations but the same thickness as shown in FIG. 6. Because the multiple RESURF zones can more reduce the electric-field concentration, this configuration is more preferable. A sheet carrier concentration of any one of the RESURF zones is set to a higher level than another RESURF zone that is located the gate-electrode side thereof.

The contact areas or the RESURF zone area can be formed by a selective regrowth instead of an ion implantation. More particularly, after etching a part of the substrate by from 30 nanometers to 100 nanometers depth, a layer is grown selectively so that the sheet carrier concentration can be 1×10¹² cm⁻² to 5×10¹³ cm⁻². The selectively grown layer is doped with an impurity at a predetermined concentration by an ion implantation, and thus the contact area is formed.

As described above, according to an aspect of the present invention, it is possible to produce a normally-off-type field effect transistor having high breakdown voltage and suitable for large-current applications. Specifically, a field effect transistor mainly formed with GaN as a III-nitride semiconductor can obtain higher breakdown voltage and lower on-resistance than breakdown voltage and on-resistance of a conventional Si electronic device, which allows producing a small-sized and low-loss electronic device.

Although the invention has been described with respect to the specific embodiments for the complete and clear disclosure, the invention is not limited to the specific embodiments and is to be construed as embodying all modifications and alternative constructions that may occur to one skilled in the art that fairly fall within the basic teaching herein set forth.

What is claimed is:

1. A III-nitride semiconductor field effect transistor comprising:
an active layer of a first conductive-type including a channel area;
a first contact area and a second contact area of a second conductive-type formed at positions across the channel area;
a source electrode formed on the first contact area;
a drain electrode formed on the second contact area;
a gate electrode formed above the channel area via a gate insulating layer; and
a reduced surface field zone of the second conductive-type formed in the channel area at a position close to the second contact area, said reduced surface field zone having a thickness of 30 nanometers to 100 nanometers.

2. The III-nitride semiconductor field effect transistor according to claim 1, wherein said reduced surface field zone has a sheet carrier concentration of 1×10¹² cm⁻² to 5×10¹³ cm⁻².

3. The III-nitride semiconductor field effect transistor according to claim 1, wherein at least one of said first contact area and said second contact area has a thickness of 30 nanometers to 100 nanometers.
